(19) United States
(12) Patent Application Publication
(10) Pub. No.: US 2010/0184297 A1
(43) Pub. Date: Jul. 22, 2010

(54) METHOD FOR PROTECTING SEMICONDUCTOR WAFER AND PROCESS FOR PRODUCING SEMICONDUCTOR DEVICE

(76) Inventors: Mikio Takagi, Kawasaki-shi (JP); Seiichi Takahashi, Susono-shi (JP)

Correspondence Address: BIRCH STEWART KOLASCH & BIRCH, PO BOX 747, FALLS CHURCH, VA, 22040-0747, US

(21) Appl. No.: 12/665,529

(22) PCT Filed: Jun. 20, 2008
(86) PCT No.: PCT/JP2008/061331

§ 371 Date: Feb. 24, 2010

(30) Foreign Application Priority Data
Jun. 22, 2007 (JP) 2007-165279

(51) Int. Cl. H01L 21/306

(52) U.S. Cl. 438/706; 257/E21.215

(57) ABSTRACT

[Task] In a proposed protection method, re-oxidation of a semiconductor wafer is prevented. The method is appropriate for fine patterned semiconductor device. A wafer is dry etched and is subjected to a next step of forming an electrode material film. The dry-etched wafer is maintained not re-oxidized until the next step. The dry etching reaction products are appropriately removed.

[Means for Solution] A wafer, on which the dry etching reaction products remain, is protected by the reaction products. The wafer is held in an inert gas protective atmosphere having a pressure of 50 Pa or more and an atmospheric pressure or less, or is held in air equivalent to the air of a clean room or in a gas-mixture atmosphere of said air and an inert gas. The reaction products are decomposed and removed by heating immediately before the formation of an electrode-material film.

### TECHNICAL FIELD

The present invention relates to a protection method for preventing re-oxidation from occurring after oxide film present on the surface of a semiconductor wafer is removed by dry etching. The present invention also relates to a method for producing a semiconductor device, in which dry etching, protection for preventing re-oxidation, and subsequent steps are carried out. In a subsequent step, for example, a CVD film is formed to fill a contact hole with an electrode material.

General treatments in a production process of a semiconductor wafer include: delineating insulating film on the surface of a semiconductor wafer by use of a resist; removing the delineated insulating film; forming a layer of electrode material; and filling a contact hole with the electrode material. The electrode material is thus deposited on the exposed silicon. Since the native oxide film formed on the surface of a semiconductor wafer increases contact resistance, various methods have been proposed to remove the native oxide film prior to film formation. Various post-removal protection methods have also been proposed.

### BACKGROUND TECHNIQUES

According to a method proposed in Patent Document 1: Japanese Unexamined Patent Publication (kokai) Hei5-217919, a native oxide film is removed by a single wafer system, and film of an electrode material is formed by a batch system. Wafers are taken out of a wafer cassette one by one and each Si wafer is washed with hydrofluoric acid gas to remove the native oxide film. Subsequently, reaction products are removed by means of heating in the same reaction chamber in which removal procedure was performed. The Si wafers are temporarily stored in a preparatory chamber having a protective inert gas atmosphere and are then treated in a batch-type treating furnace for film formation. Robots perform a sequence of these operations.

In a method proposed in Patent Document 2: Japanese Unexamined Patent Publication (kokai) No. 2004-343094, a native oxide film or the like is removed by dry etching using a gaseous mixture of HF and NH₃ at 100 to 600 degrees C. Chemical oxide film, which is formed by a solution mixture of H₂O₂ and NH₄OH, exhibits electric properties superior to those of native oxide film. Subsequently, Si film doped with Ge impurity is caused to grow by consecutively supplying monosilane and mono germanium into the same apparatus in which removal of oxide film was performed.

Non-patent Document 1, Published Technical Bulletin 2005-501872 of Japan Institute of Invention and Innovation relates to a method for removing a native oxide film, using not plasma but NH₃ and HF. A gas mixture of NH₃ and HF is caused to react with the native oxide film and the resultant ammonium silicofluoride is decomposed. A chamber for forming ammonium silicofluoride and a chamber for decomposing the ammonium silicofluoride are arranged in parallel and are gas-tightly communicated with each other via a common load-lock chamber. The load-lock chamber is located beneath the forming and decomposing chambers, which are mentioned above. The interior of the load-lock chamber is a nitrogen or vacuum atmosphere.

In a batch-type treating method of wafers proposed in Patent Document 3, Japanese Unexamined Patent Publication (kokai) No. 2003-124172, native oxide film is removed by a plasma gas mixture of, for example, NF₃ and hydrogen gas. A reaction product such as silicon fluoride is removed from wafers by heating, and the wafers are then displaced into a load-lock chamber. Its interior has a nitrogen protective atmosphere having atmospheric pressure. The treated wafers are mounted on a boat and are then transferred out of the load-lock chamber.

Patent Document 4, Japanese Unexamined Patent Publication (kokai) No. Hei10-209111 describes hydrogen-termination for the purpose of preventing re-oxidation. That is, native oxide film of a wafer is removed and is then washed with hydrofluoric acid or the like. According to the proposal of this patent document, vapor-drying with isopropyl alcohol, heat treatment to desorb the isopropyl alcohol, and thermal oxidation are subsequently carried out, following the hydrogen termination.

Patent Document 5, PCT/JP2006/316074 (International Application filed on Aug. 15, 2006 by both of the present applicants) relates to an etching method of native oxide film by a single-wafer or batch method. According to the proposal of this patent document, N₂ and/or H₂ gas is activated by microwave and is mixed with NF₃ or the like. The native oxide film is removed by use of the gas mixture at a temperature of 50 degrees C. or lower, followed by hydrogen termination. The wafer(s) is then cooled by inert gas having a temperature of 0 to −(minus) 30 degrees C.

A pattern rule in the year of 2002 was 133 nm. Wafers were therefore treated at a fine degree of this pattern rule, dry-etched, and subjected to removal of native oxide film. Even when the wafers, after removal of native oxide film therefrom, were allowed stand in a clean room for 8 hours, the problem of re-oxidation did not occur. That is, a native oxide film was not formed again. Later, pattern rules have gradually become even finer and an announcement regarding mass production of 45-nm semiconductors was released in April 2007 (Non-patent Document 2, Nikkei Newspaper dated Apr. 10, 2007.)

Patent Document 1: Japanese Unexamined Patent Publication (kokai) No. Hei5-217917
Patent Document 2: Japanese Unexamined Patent Publication (kokai) No. 2004-343094
Patent Document 3: Japanese Unexamined Patent Publication (kokai) No. 2003-124172
Patent Document 4: Japanese Unexamined Patent Publication (kokai) No. Hei10-209111

### Patent Document 5: PCT/JP2006/316074

Patent Document 5: Japanese Unexamined Patent Publication (kokai) No. Hei7-121248

### Non Patent Document 1: Publish Technical Bulletin 2005-501872 of Japan Institute of Invention and Innovation

Non Patent Document 2: Nikkei Newspaper dated Apr. 10, 2007
Non Patent Document 3: Beginners Handbook 32 “Semiconductor Nanoprocess from the Beginning”, Author: Kazuo, MAEDA, published by Industrial Examination Co., Ltd., published on Feb. 10, 2000, page 122.

### DISCLOSURE OF INVENTION

### Problems to be Solved by Invention

A wafer is subjected to dry etching, and decomposing and removal of resultant dry etching reaction products by heating, together with hydrogen termination. The so-treated wafers are stored in a chamber of inert-gas atmosphere. An electrode material is filled by a batch-type CVD. Since fine patterning of semiconductor has advanced, re-oxidation occurred during the stand-by time of the semiconductor producing line comprising the steps described above. Therefore contact resistance of the wafers was disadvantageously varied from wafer to wafer. According to the method of Patent Document 1, native oxide film is removed by use of a single wafer system, and dry-etching reaction products are removed by using an infrared ray lamp for approximately 1 minute and at a temperature in the vicinity of 70 degrees C. The native oxide film is dry etched and reaction products are removed in the identical reaction chamber. That is an identical reaction chamber is used for dry etching of a native oxide film, its decomposition and removal of reaction products. Dry etching temperature is desirably 50 degrees C. or lower, while heating up to approximately 100 degrees C. is necessary for decomposition and removal of reaction products. It is therefore difficult to maintain the temperature of the interior of the identical reaction chamber to a level appropriate for both the reactions of native oxide removal and decomposition and removal of reaction products. When a preceding step, i.e., dry etching, and a succeeding step, i.e., CVD, are carried out in an identical apparatus, as in Patent Document 2, although the problem of re-oxidation does not arise, a preceding single-wafer step and a succeeding batch step cannot be combined in an identical step. In addition, the particles are liable to be disadvantageously formed.

It is an object of the present invention to provide a protection method for a semiconductor silicon wafer for preventing its re-oxidation while surmounting the prior art techniques mentioned above and can be applied to finely patterned semiconductor devices.

It is also an object of the present invention to provide a method for producing a semiconductor device, in which a dry etched wafer can be prevented from re-oxidation until a subsequent step of forming an electrode-material film, and, dry etching reaction products can be appropriately removed.

### Means for Solving the Problems

In accordance with the present invention, there is provided a method for protecting the surface of a semiconductor silicon wafer, characterized in that: etching gas containing fluorine is caused to react with oxide film present on the surface of a semiconductor silicon wafer, thereby forming reaction products; and, the reaction products are decomposed and removed by heating immediately before formation of a film. Specifically, an etching gas containing fluorine is caused to react with oxide film present on the surface of a semiconductor wafer. Reaction products thus formed remain on the surface of a semiconductor silicon wafer. The wafer is held for 8 hours or less in an inert gas-mixture protective atmosphere having a pressure of 50 Pa or more but atmospheric pressure or less at a temperature of 100 degrees C. or less. Alternatively, a wafer may be held in a protective atmosphere, which may be air equivalent to the air of a clean room. Alternatively, a wafer may be held in a gas mixture of such air and inert gas. Holding time in the latter protective atmospheres is within two hours. After dry etching of oxide film, the surface of the semiconductor silicon wafer is thus protected until immediately before formation of electrode material film. In addition, the present invention also relates to a method for producing a semiconductor device, wherein oxide film present on the surface of a semiconductor silicon wafer is dry etched, and a film of electrode material is subsequently formed and connected with the semiconductor silicon, characterized in that the inventive surface protection is carried out, and then said reaction product is decomposed and removed by heating immediately before the step of forming the film of electrode material.

Herein, the oxide film is thermal oxidation film, a native oxide occurring on an Si substrate, and the like. An example of the native oxide film is mainly described hereinafter.

The etching gas, which can be used in the present invention, is hydrofluoric acid, a gas mixture of HF and NH₃, a gas mixture described in Patent Document 5, or the like. In Patent Document 5, at least one of hydrogen and nitrogen, and a second gas, which includes neither carbon (which produces particles) nor oxygen (which causes oxidation), but includes fluorine, are mixed. Specifically, such gases as H, N, and NH₃, which may or may not be activated with a microwave of 2.45 GHz, and HF₃ are mixed to be used as the etching gas. Alternatively, there may be employed a mixture of microwave-radiated NH₃ or non-microwave radiated HF and NF₃, to provide a gas mixture capable of serving as the etching gas. Since reaction of a gas mixture of microwave-radiated gas and NF₃ does not proceed at 60 degrees or more, preferably, reaction is performed at 50 degrees C. or less, particularly preferably at 30 degrees C. or less.

The present inventors used a gas mixture of microwave-radiated H₂ and NH₃ gases and NF₃ to provide contact holes having different widths (H) in a 500-nm thick SiO₂ film; heated reaction products for decomposition and removal; simultaneously performed hydrogen termination; and, filled polycrystalline silicon to connect the polycrystalline silicon with the exposed Si. The treated wafers are stored in a clean room for a period between the formation of a contact hole and deposition of a P-doped polycrystalline silicon film. The present inventors examined the relationship between the holding time elapsed in the clean room and a holding time (t) during which contact resistance did not increase. The following relationships were obtained. H=90 nm, t=3 hours; H=80 nm, t=90 minutes; H=70 nm, t=50 minutes; H=60 nm, t=40 minutes. Contact holes having widths of 90 nm, 80 nm, 70 nm and 60 nm (H) were provided by dry etching through the 500-nm thick SiO₂ film of wafers. With reaction products being left on the wafers, the wafers were allowed to stand in a load-lock chamber having a nitrogen-gas protective atmosphere for 8 hours. No increase in contact resistance was observed. Similar wafers, on which reaction products were left, were allowed to stand in a clean room for 2 hours. No increase in contact resistance was observed. A phenomenon observed was that moisture contained in minor amounts in air rendered the surface portion of a reaction-product-layer porous. Presumably, contact resistance changed due to this phenomenon.

The preceding paragraph describes the relationship between the degree of fine patterning of a semiconductor device and re-oxidation of atomic Si, which is exposed on the bottom of a contact hole. This relationship is construed as follows. Incidentally, the diameter of a contact hole is determined by a pattern rule, and it is 70 to 90 nm in current semiconductor devices. However, a pattern rule of 40 nm may be realized in two or three years of time.
(a) A large contact hole exposes a large surface area of Si crystals. Even if such Si crystals are somewhat re-oxidized, contact resistance only slightly decreases.
(b) When a semiconductor silicon wafer (hereinafter referred as “the wafer”) is heated to decompose and remove reaction products and the wafer is held in an inert gas protective atmosphere, re-oxidation cannot be satisfactorily prevented, provided that the contact hole is fine and that the holding time is a few hours or more. The mentioned hydrogen termination cannot satisfactorily prevent re-oxidation as well.
(c) When etching gas reacts with silicon oxide of usually approximately 2-nm thick native oxide film, silicon fluoride, ammonium silicofluoride, and the like are produced as reaction products and cover atomic silicon. The reaction products deposit at the same locations where the native oxide has been etched. The reaction products are, therefore present on the bottom of a contact hole, which must be prevented from re-oxidation.
(d) An ordinary clean room is not particularly intended to decrease humidity, and, therefore, its relative humidity may amount to approximately 40%. Moisture level of such a clean room is very high to deteriorate dry etching reaction products. Dry etching reaction products are thus sensitive to moisture contained in a small amount in air. In a clean room, the protection effect is maintained for a maximum of 2 hours. In an inert gas atmosphere, however, dry etching reaction products can maintain protective effect for as long as 8 hours.
(e) Holding time in a clean room within 30 minutes does not cause such oxidation of atomic Si as to vary the contact resistance.

According to the present invention, dry etching reaction products of native oxide film are utilized as a re-oxidation resistant protective film until immediately before formation of an electrode material film. While a wafer is protected, it is exposed to an inert gas protective atmosphere formed of such gases as industrially pure nitrogen, argon, or the like, containing a low level of moisture that may react with the reaction products. When the pressure of such an inert gas atmosphere is less than 50 Pa, since this is lower than the dry etching pressure, reaction products are liable to decompose. When the pressure is more than normal pressure, a special protective vessel is needed and is not economical. In an inert gas atmosphere, the dry etching reaction products maintain their protection effect for approximately 8 hours. A semiconductor production line is usually operated in an 8-hour shift system. Therefore, protected wafers can be transferred to the next shift.

Moreover, a wafer can be exposed to the space of a clean room, that is, a wafer can be exposed to air. Alternatively, a wafer can be protected in a wafer storing box or the like located in a clean room by flowing an inert gas thereinto. Since the moisture in air deteriorates the protective film of reaction products, their protecting effect lasts approximately 2 hours. When the temperature of a space to which a wafer is exposed exceeds 100 degrees C., the reaction products are liable to decompose.

When the inventive method is applied to the production of semiconductor devices having a pattern rule of 50 to 90 nm, protection effect attained is that non-attainable by a conventional hydrogen termination. The inventive method can be applied to semiconductor devices having a larger pattern rule. In this case, protection effect that can be attained is equivalent or superior to the conventional one.

A method for producing a semiconductor device according to the present invention is now described in detail.

In the present invention, etching reaction products of native oxide film are decomposed and removed in an apparatus for forming a film of electrode material. This decomposition and removal is performed immediately before formation of the electrode-material film by heating to 130 to 200 degrees C., in an apparatus for forming an electrode-material film, such as P-doped polycrystalline silicon, Al, Cu, Co, Ni, WSi₂, CoSi₂, TiSi₂, NiSi₂ or the like. The electrode material Cu film is formed by electroless Cu plating. Underlying TiN is formed beneath the electroless Cu plating in a sputtering apparatus or a CVD apparatus, and then Al is vapor-deposited on the underlying TiN film. A multi-layer TiN/Al/Cu may be formed. Other electrode-forming material is shown in Non-Patent Document 3: Beginners Handbook 32 “Semiconductor Nano process from the Beginning”, Authored by Kazuo MAEDA, Industrial Examination Co., Ltd., published on Feb. 10, 2000, page 122.

In the present invention, the entity of underlying TiN, Cu, and the like is collectively referred to as the electrode material. It is intended to form the lowermost layer of electrode-material film on certain number of wafers. When said number of wafers is loaded in the apparatus and the lowermost layer is just ready for forming, it is “immediately before formation of an electrode material” meant herein. Specifically, when the decomposition and removal of native oxide film and the formation of electrode-material film are carried out in different apparatuses, exposed atomic Si is oxidized while the wafers are transferred from one apparatus to another apparatus. In addition, for example, one hundred wafers are to be subjected to a CVD process for forming polycrystalline silicon film, and twenty five wafers are subjected to dry etching. In this case, four CVD treatments provide the number of wafers to be treated in a CVD process. It is important that these hundred wafers be altogether subjected to removal of reaction products so that the contact resistance of these hundred wafers is made uniform. Decomposition of reaction products initiates at approximately 100 degrees C. and completes at approximately 200 degrees C. When the temperature is elevated to a temperature for forming electrode material film, gas evacuation is carried out during the temperature elevation, when volatile materials of reaction products, such as H and N, are exhausted and removed as the temperature elevates within the mentioned range.

In accordance with the present invention, there is also provided a method for producing a semiconductor device, wherein an oxide film present on the surface of a semiconductor silicon wafer is dry etched by a single wafer method or batch method, and, subsequently, electrode-material film to be connected with semiconductor silicon is formed by a batch method (with the proviso that the number of wafers treated by a batch-type formation of an electrode-material film is greater than the number of wafers treated by a batch-type dry etching), characterized in that the surface protection according to claim 1 is carried out until the number of treated wafers amounts to the number of wafers that are treated in the batch type formation of an electrode-material film subsequently, decomposition and removal of said reaction products on all of the semiconductor silicon wafers is carried out in the identical apparatus by heating, and, subsequently within 30 minutes the semiconductor silicon wafers are displaced to an apparatus for forming an electrode-material film. In this method, protection by reaction products is carried in the same manner as described hereinabove. This method is characterized in that decomposition and removal of reaction products and formation of electrode-material film are carried out in apparatuses different from each other. As a result, when a wafer is being transferred to an apparatus for forming an electrode-material film, although atomic Si is exposed to the air in a clean room, an inert gas atmosphere of a load-lock chamber, or the like, since the exposure time is within 30 minutes, contact resistance can be prevented from variation.

The production method of a semiconductor device according to the present invention is advantageous over the methods of Patent Documents 1 and 5 in the following points.

(a) Preventive effect of re-oxidation is high. It is possible to suppress an increase in contact resistance of a fine-pattern semiconductor device. (b) Native oxide film can be etched in a reaction chamber of an etching apparatus while maintained at low temperature. Reaction speed can therefore be enhanced. (c) In the apparatus for forming an electrode material film, protective films on the wafers are removed simultaneously for all the wafers. Contact resistance is therefore stabilized. (d) A single-wafer type dry etching method and a batch-type method for formation of electrode-material film can be combined in any desired manner. Any desired number of wafers can be treated batchwise. A constant contact resistance can be obtained, no matter how a batch treatment and a single wafer treatment are combined, and no matter how many wafers are treated. It is therefore possible to suppress re-oxidation during the stand-by time of a semiconductor production line.

Preferred embodiments of the present invention are described hereinbelow.

Patent Document 5 proposes cooling by an inert gas. When the inert-gas cooling is carried out after dry etching of the native oxide film, generation of particles can be prevented. After dry etching, cooling is carried out in a dry etching chamber or a special cooling chamber. An inert gas having a temperature of 0 to −(minus) 30 degrees C. is ejected on either or both surfaces of a wafer, thereby cooling the wafer. After cooling, the wafer is displaced to a lock-lock chamber or a clean room. Nitrogen is a preferable inert gas, because it does not react with semiconductor and is inexpensive. Nitrogen is effective for cooling in a range of 0 to −(minus) 30 degrees C., particularly −(minus) 10 to −(minus) 20 degrees C. A portion of the reaction products is liable to be converted to particles, unless this cooling is carried out.

Preferably, nitrogen is heat exchanged with liquid having a temperature of from 0 to −(minus) 30 degrees C., for example, brine, ethylene glycol, or the like using a dual tube, a fin, or the like, to thereby adjust the temperature of nitrogen to the temperature of the liquid. An isothermal treating apparatus for producing the constant-temperature gas is disclosed in Patent No. 6 Japanese Unexamined Patent Publication (kokai) No. Hei7-121248 or the like. A commercially available thermo chiller can also be used. A thermo chiller is sold by SMC Co., Ltd., and has heretofore been used to keep a reaction tank of an etcher to a constant temperature of −(minus) 20 degrees C. to +40 degrees C. at an allowance of ±3 degrees C. In the present invention, chiller for cooling an etcher may be utilized to by-pass a part of the cooling gas. Alternatively, a tank of a coolant liquid, such as brine, already installed in a plant is utilized, and heat exchange may be carried out in a semiconductor surface-treatment apparatus.

### BRIEF EXPLANATION OF DRAWINGS

FIG. 1 A cross-sectional view of a batch-type etching apparatus of native oxide film according to an embodiment of the present invention.

FIG. 2 A cross-sectional view cut along line II-II of FIG. 1.

FIG. 3 A cross-sectional view cut along line III-III of FIG. 1.

FIG. 4 A cross-sectional view of a single-wafer type etching apparatus according to an embodiment of the present invention.

FIG. 5 A plan view of a reaction-gas ejector.

FIG. 6 A cross-sectional view cut along line IV-IV of FIG. 4.

FIG. 7 A drawing showing a wafer supporting jig according to another embodiment of the present invention.

FIG. 8 A vertical cross-sectional view of a CVD apparatus.

FIG. 9 A horizontal cross-sectional view along line IX-IX of FIG. 8.

### BEST MODES FOR CARRYING OUT THE INVENTION

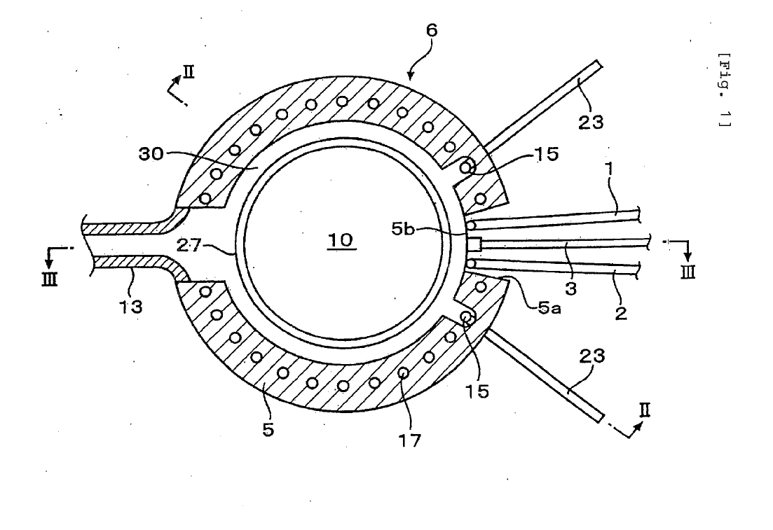

An embodiment of a batch type dry etching apparatus for native oxide film according to the present invention is hereinafter described with reference to FIGS. 1-3. The dry etching apparatus has a two-stage structure consisting of a treatment preparatory chamber 21 and a reaction chamber 30.

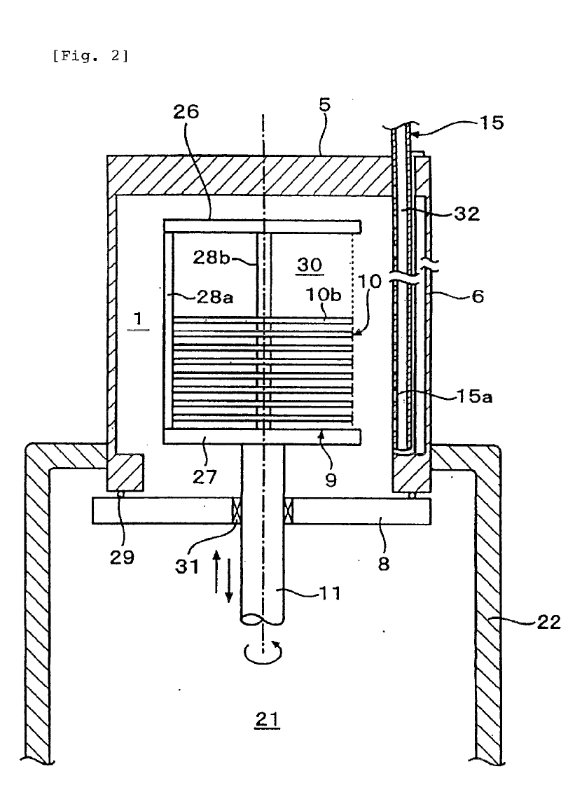

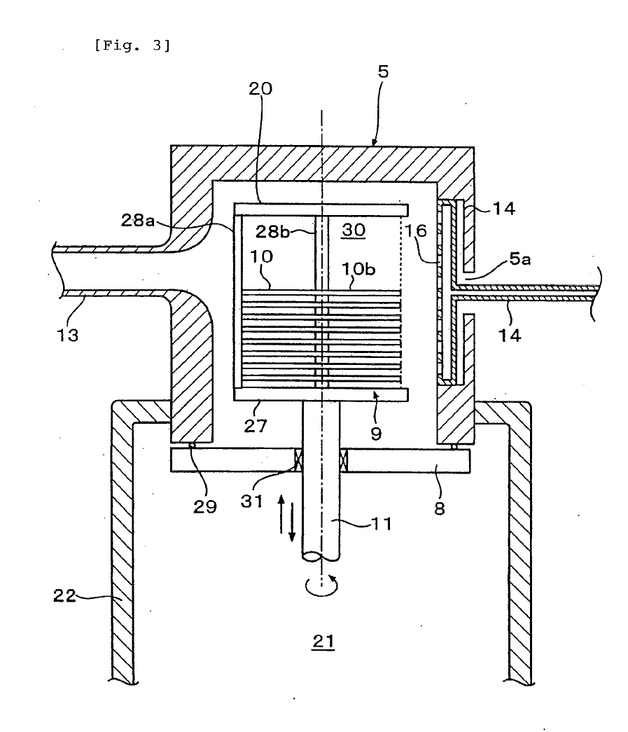

FIG. 1 shows a horizontal cross-sectional view of an apparatus for dry etching a native oxide film on a plurality of wafers. FIG. 2 is a cross-sectional view along the line II-II. FIG. 3 is a cross-sectional view along the line III-III. The first gas is H₂, N₂, or the like in molecular form, or NH₃ or the like in compound form and the second gas is NF₃ or the like. In these drawings, a reaction tank 5 has an inner surface of anodized aluminum and is also provided with a cut-off portion 5a. The first gas inflowing conduit 3 and the second gas inflowing conduits 1, 2 have openings on the inner surface 5a. A partition plate 5b supports a front end of conduits 1, 2, 3 (FIG. 1). The front end of each of these gas-inflowing conduits 1, 2, 3 is in the form of a vertically elongated chamber. Gas ejecting apertures, the number of which is approximately equal to the number of wafers, have openings in the vertically elongated chambers. A microwave generator of 2.45 GHz may be attached to the first gas-flowing conduit 3.

A reaction tank 5 is in the form of a hollow aluminum cylinder, in which a cooling channel 17 meanders. A cooling medium maintains the interior of the reaction tank at a preferable dry etching temperature and also at such a temperature that aluminum is not corroded by a fluorine-based gas. Since the dry etching apparatus according to the present invention is not additionally provided with a heating means for removal of reaction products and hydrogen termination, the temperature of the apparatus does not rise due to these means.

A gas-exhausting tube 13 withdraws the reaction gas and unreacted gas out of the vessel and is situated symmetrically to the gas inflowing conduits 1, 2, 3. A valve and a pump (not shown) are located on the gas-exhausting tube 13. The reaction chamber 30, in which wafers 10 are located, is sucked to a pressure of 66 Pa (0.5 torr) to 2.5 kPa (20 torr).

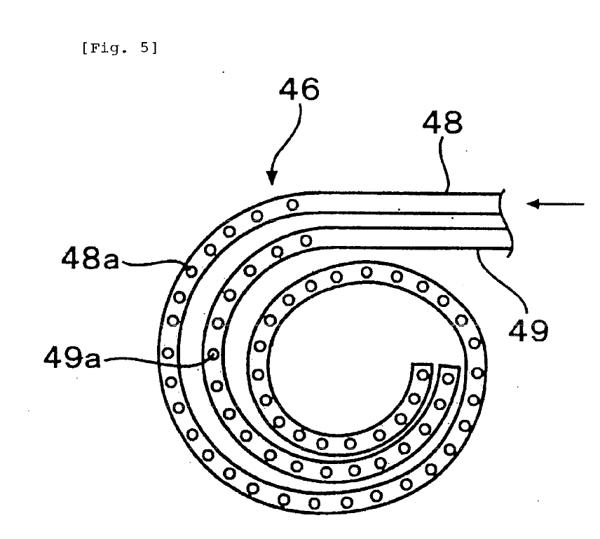

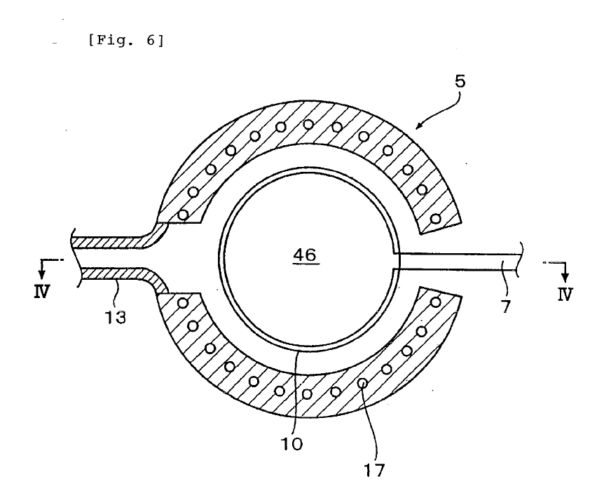

Wafers 10 are placed in the reaction chamber 30 by a jig 9 (see FIG. 2) with their surfaces 10b being vertically oriented. The jig 9 is secured to a rotary shaft 11 and is lifted or lowered in the reaction chamber 30. In the condition shown in FIG. 2, the bottom plate 8 and the reaction tank 5 are firmly secured to each other via an O-ring 29. The rotary shaft 11 is rotated on a bearing 31 at a revolution number of for example approximately 5-10 rpm. In the jig 9, a top plate 26 and a bottom plate 27 have a slightly greater diameter than the wafers 10. Three vertical column 28a, b, c (not shown in FIG. 1) are located between the top plates 26 and the bottom plate 27, which are held by the vertical columns. The vertical columns 28a, b, c are provided with claws (not shown) for holding the wafers 10 (FIGS. 5 and 6). The bottom side of the reaction chamber 30 is closed by a bottom plate 8. When the rotary shaft 11 rotates via a bearing 31 mounted on a bottom plate 8, the jig 9 rotates together with a wafer 10. The reaction tank 30 and treatment preparatory chamber 21 may be vertically reversed. A reaction tank of the treatment preparatory chamber is denoted by 22.

In the present invention, the pressure in a reaction chamber is reduced to vacuum, and, subsequently a reaction gas consisting of first and second gases is introduced into the reaction chamber to remove native oxide film or the like.

Preferable etching conditions are as follows.

### (a) Microwave Activated Etching

Power of Microwave
8-inch wafer: 3000 W
12-inch wafer: 6000 W
Gas condition
Pressure—H₂, N₂—0.13 Pa˜1.3 kPa
Flow rate—H₂, N₂—1 L/min
   (b) Etching without microwave irradiation
Pressure and flow rate are adjusted greater than (a).

Nitrogen gas for cooling is ejected through apertures 15a of an ejecting tube 15 to cool the wafers 10. After stopping ejection of the nitrogen gas for cooling, nitrogen gas is caused to flow through the first gas inflowing tube 3 to bring the interior of the reaction chamber to normal pressure. The wafers 10 are lowered together with the jig 9 and bottom plate 8, displaced to a treatment preparatory chamber 21, and then transferred to a clean room by use of a fork-like jig.

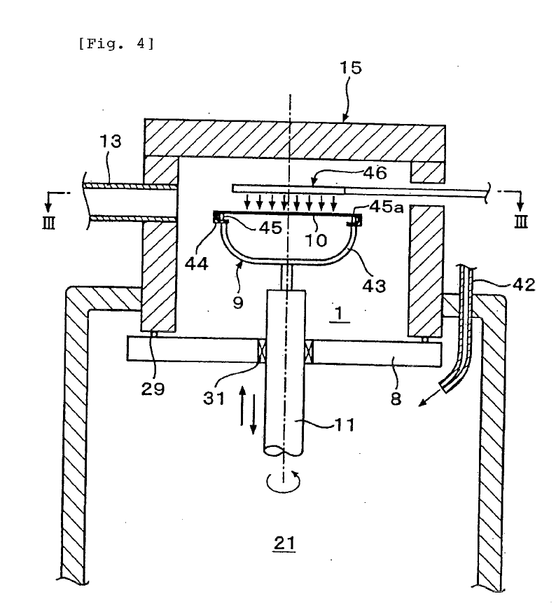

A single-wafer type dry etching method for native oxide film according to the present invention is described hereinafter with reference to FIGS. 4-7. In these drawings, the same elements as those shown in FIGS. 1-3 are denoted by the same reference numerals. Their functions are also the same as those described with reference to FIGS. 1-3.

The apparatus shown in FIGS. 4-7 has a vertical two-stage structure consisting of a reaction chamber 1 and a treatment preparatory chamber 21. Incidentally, the reaction chamber 1 and the treatment preparatory chamber 21 may be vertically reversed.

A jig 9 shown in FIG. 4 has a supporting arm 43 and an L-shaped front end 44 rigidly secured by the supporting arm. A pin extends vertically upward from the L-shaped front end and supports the wafers 10. 46 (FIGS. 1, 3) schematically illustrates a dry-etching gas ejector of the first and second gases.

In the dry-etching gas ejector (FIG. 5), a first-gas inflowing tube 48 for passing a molecular gas, such as H₂, N₂, or a compound gas such as NH₃ and a second-gas inflowing tube 49 are arranged in dual spiral form. The first gas and second gas are ejected through the ejecting aperture 48a and the second gas, such as NF₃, is ejected through the ejecting aperture 48a, 49b. The first-gas inflow tube 18 may be additionally provided with a microwave generator of 2.45 GHz. A native oxide film on the wafer 10 is dry etched at a position shown in FIG. 4. Subsequently, the wafer 10 is lowered to the treatment preparatory chamber 12, where nitrogen gas for cooling is ejected on the wafer 10 through a single gas ejecting conduit 42.

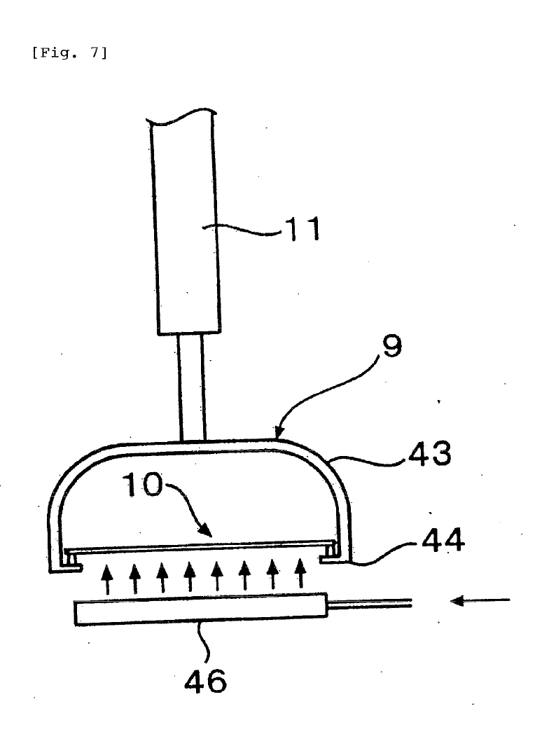

FIG. 7 shows an ejecting tube 46, through which a dry-etching gas is ejected upward, that is, opposite to FIG. 4.

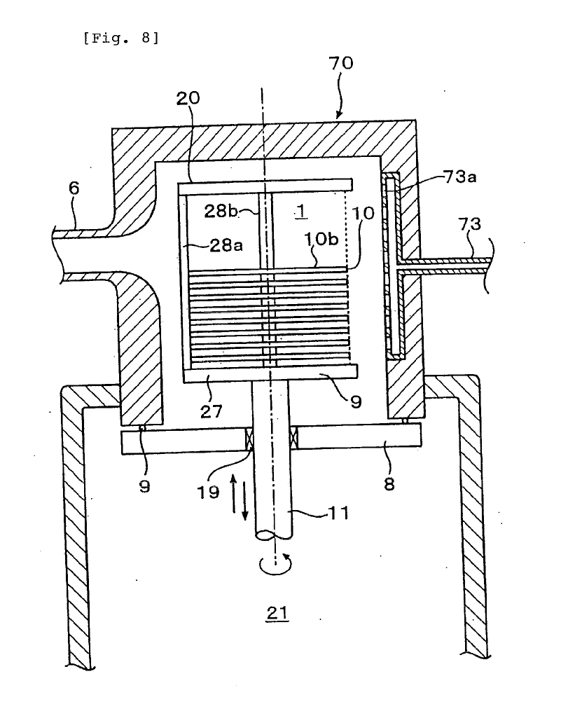

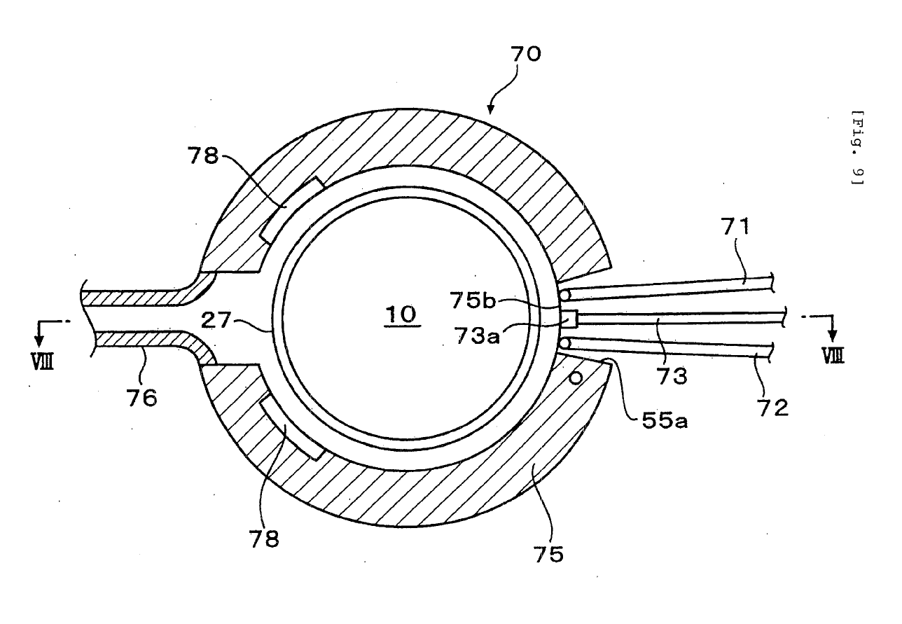

FIGS. 8 and 9 illustrate apparatuses according to some embodiments of the invention, in which decomposition and removal of reaction products and CVD for forming an electrode-material film are performed. In these drawings, 70 denotes a reaction tank, and each of 71, 72, 73 denotes an inflowing tube for a reaction gas or carrier gas.

75 denotes a reaction tank. 76 denotes a gas exhausting tube. 78 denotes a lamp heater for decomposing reaction products. A lamp heater 78 heats the wafers 10 to a temperature of 100 to 200 degrees C., thereby vaporizing the dry etching reaction products of native oxide film. The vaporized matters are exhausted from the gas-exhausting tube 76. Further, the temperature is elevated through heating with a lamp, up to a growth temperature of polycrystalline silicon or the like.

### INDUSTRIAL APPLICABILITY

As is described hereinabove, according to the present invention, it is possible to prevent re-oxidation of silicon of a fine semiconductor device and to stabilize contact resistance. This leads to increase recovery.

The description provided hereinabove deals with the case of dry etching of native oxide film. When thicker thermal oxidation film is dry etched, such a reaction product as silicon fluoride covers atomic Si also in this case. Therefore, a wafer in such a state can be stored in a clean room and be subsequently subjected to CVD or the like.

1. A method for protecting a surface of a semiconductor silicon wafer, characterized in that: etching gas containing fluorine is caused to react with oxide film present on the surface of a semiconductor silicon wafer, thereby forming reaction products; and, subsequently, said reaction products are decomposed and removed immediately before the formation of an electrode-material film.

2. A method for protecting a surface of a semiconductor silicon wafer according to claim 1, characterized in that, after formation of said reaction products, the semiconductor silicon wafer is held within 8 hours in an inert gas protective atmosphere having a pressure of 50 Pa or more and an atmospheric pressure or less at a temperature of 100 degrees C. or less, or is held in air equivalent to the air of a clean room or in a gas-mixture atmosphere of said air and an inert gas, within 2 hours, thereby protecting the surface of a semiconductor silicon wafer after dry etching of the oxide film and until immediately before the formation of an electrode-material film.

3. A method for producing a semiconductor device, wherein oxide film present on the surface of a semiconductor silicon wafer is dry etched, and, subsequently, a film of electrode material is formed and connected with the semiconductor silicon, characterized in that the surface protection according to claim 1 or 2 is carried out, and subsequently the reaction products are decomposed and removed by heating immediately before the formation of film of an electrode material.

4. A method for producing a semiconductor device, wherein oxide film present on the surface of a semiconductor silicon wafer is dry etched by a single wafer method or batch method, and, subsequently, electrode-material film is formed and connected with semiconductor silicon by a batch method (with the proviso that the number of wafers treated by a batch-type formation of an electrode-material film is greater than the number of wafers treated by a batch-type dry etching), characterized in that a surface protection according to claim 1 or 2 is carried out until the number of treated wafers amounts to the number of wafers that are treated in the batch type formation of an electrode-material film, subsequently, decomposition and removal of said reaction products on all of the semiconductor silicon wafers is carried out in the identical apparatus by heating, and, subsequently within 30 minutes the semiconductor silicon wafers are displaced to an apparatus for forming electrode-material film.

5. A method for producing a semiconductor device according to claim 3, wherein said etching gas is a gas mixture of a first gas consisting of at least one of hydrogen and nitrogen and a second gas, which is free of carbon and oxygen and contains fluorine.

6. A method for producing a semiconductor device according to claim 4, wherein said first gas is microwave activated.

7. A method for producing a semiconductor device according to claim 6, characterized in that said dry etching is carried out at a temperature of 50 degrees C. or less.

8. A method for producing a semiconductor device according to claim 7, characterized in that after said dry etching reaction, an inert gas having a temperature of −(minus) 30 to +(plus) 25 degrees C. is ejected on the semiconductor silicon wafer, on which reaction products remains, thereby cooling the semiconductor silicon wager.
